(19) United States
(12) Patent Application Publication
(10) Pub. No.: US 2019/0294957 A1
(43) Pub. Date: Sep. 26, 2019

(54) ARITHMETIC DEVICE AND ARITHMETIC METHOD

(71) Applicant: Toshiba Memory Corporation, Tokyo (JP)

(72) Inventor: Fumihiko Tachibana, Yokohama Kanagawa (JP)

(21) Appl. No.: 16/122,123

(22) Filed: Sep. 5, 2018

(30) Foreign Application Priority Data
Mar. 22, 2018 (JP) 2018-055166

(51) Int. Cl. G06N 3/063; G06N 3/04; H03K 5/134

(52) U.S. Cl. CPC G06N 3/0635; H03K 2005/00195; H03K 5/134; G06N 3/04

(57) ABSTRACT

An arithmetic device includes: an arithmetic circuit that includes arithmetic elements connected in series, and sequentially performs multiple repetitions of arithmetic processing, wherein each of the arithmetic elements receives a first time signal and a second time signal, and generates a third time signal and a fourth time signal obtained by delaying the first and second time signals by a time corresponding to a weight coefficient and input data; a converter that converts a difference between the third and fourth time signals output from the arithmetic circuit into an analog signal or a digital signal for every multiple repetition of arithmetic processing; an integrator that integrates analog signals or digital signals converted by the converter; and a comparator that compares the integration result by the integrator with a reference value.

### CROSS-REFERENCE TO RELATED APPLICATIONS

This application is based upon and claims the benefit of priority from Japanese Patent Application No. 2018-055166, filed Mar. 22, 2018, the entire contents of which are incorporated herein by reference.

### FIELD

Embodiments described herein relate generally to an arithmetic device and an arithmetic method used for a neural network.

### BACKGROUND

A neural network is a model devised by imitating neurons and synapses in the brain, and includes at least processing in two stages of training and inference. In the training phase, features are trained from many inputs to establish a neural network for inference processing. In the inference phase, the established neural network infers what the new input is.

In recent years, great progress has been made in a technique of the neural network. For example, a multilayer neural network having a high degree of expressing ability can be structured by deep learning in the training stage.

When the processing in the inference stage is implemented with software, it could take a lot of time in the processing and lead to higher power consumption. Accordingly, the processing in the inference stage may be performed with hardware. However, in the multilayer neural network, there are numerous parameters and a large computation volume, and therefore, the hardware configuration may become complicated.

In the multilayer neural network, a product-sum operation corresponding to each layer is repeated. In addition, between at least two layers included in the multilayer neural network, the number of product-sum operations (multiply and accumulate (MAC)) is different. The product-sum operation is performed with a processing element (PE) configured by hardware. By performing the product-sum operation by time domain, it is high-power efficient, but the number of possible product-sum operations of one layer is restricted by the number of PEs. If the number of PEs is matched with the maximum number of MACs, an area for mounting a circuit increases, and some PEs may be wasted in a layer with the small number of MACs.

### BRIEF DESCRIPTION OF THE DRAWINGS

FIG. 1 is a block diagram illustrating a schematic configuration of an inference system according to a first embodiment;

FIG. 2 is a block diagram illustrating a schematic configuration of an inference device shown in FIG. 1;

FIG. 3 is a block diagram of an arithmetic device according to the first embodiment;

FIG. 4 is a block diagram for illustrating one arithmetic unit and one functional circuit shown in FIG. 3;

FIG. 5 is a block diagram of an arithmetic element shown in FIG. 4;

FIG. 6 is a circuit diagram of a delay circuit and a switching circuit shown in FIG. 5;

FIG. 7 is a circuit diagram illustrating another configuration example of a switching circuit 25;

FIG. 8 is a circuit diagram of a converter 20 shown in FIG. 3;

FIG. 9 is a circuit diagram of a TAC, an integrator, and a comparator according to the first embodiment;

FIG. 10 is a flowchart for illustrating a product-sum operation of the arithmetic device according to the first embodiment;

FIG. 11 is a schematic diagram for illustrating the product-sum operation of the arithmetic device according to the first embodiment;

FIG. 12 is a timing diagram for illustrating an operation of the TAC according to the first embodiment;

FIG. 13 is a timing diagram for illustrating the product-sum operation of the arithmetic device according to the first embodiment;

FIG. 14 is a circuit diagram of a TDC, an integrator, and a comparator according to a second embodiment;

FIG. 15 is a timing diagram for illustrating a product-sum operation of an arithmetic device according to the second embodiment;

FIG. 16 is a timing diagram for illustrating a product-sum operation of an arithmetic device according to a modification example;

FIG. 17 is a block diagram for illustrating one arithmetic unit and one functional circuit according to a third embodiment;

FIG. 18 is a circuit diagram of an arithmetic element shown in FIG. 17;

FIG. 19 is a timing diagram for illustrating an operation of the arithmetic element according to the third embodiment;

FIG. 20 is a circuit diagram of a TAC, an integrator, and a comparator according to the third embodiment;

FIG. 21 is a timing diagram for illustrating a product-sum operation of an arithmetic device according to the third embodiment;

FIG. 22 is a circuit diagram of a signal generating circuit according to a fourth embodiment; and

FIG. 23 is a timing diagram for illustrating a product-sum operation of an arithmetic device according to the fourth embodiment.

### DETAILED DESCRIPTION

In general, according to one embodiment, there is provided an arithmetic device comprising: an arithmetic device used for a neural network, comprising:

an arithmetic circuit that includes a plurality of arithmetic elements connected in series, and sequentially performs multiple repetitions of arithmetic processing, wherein each of the plurality of arithmetic elements receives a first time signal and a second time signal, and generates and outputs a third time signal and a fourth time signal obtained by delaying the first and second time signals by a time corresponding to a weight coefficient and input data;

a converter that converts a difference between the third and fourth time signals output from the arithmetic circuit into an analog signal or a digital signal for every multiple repetition of arithmetic processing;

an integrator that integrates a plurality of analog signals or a plurality of digital signals converted by the converter; and

a comparator that compares the integration result by the integrator with a reference value.

Hereinafter, embodiments will be described with reference to the drawings. Some embodiments described below exemplify apparatuses and methods for embodying the technical idea of the present invention, and the technical idea of the present invention is not specified depending on the shape, structure, arrangement, etc. of constituent components. Each of the function blocks can be implemented in the form of hardware, software, or a combination thereof. The function blocks do not have to be categorized as in the example described below. For example, part of the functions may be implemented by a function block other than the exemplary function blocks. In addition, the exemplary function blocks may be further divided into function sub-blocks. In the following descriptions, elements having the same functions and configurations are denoted by the same reference numerals, and redundant explanations are given only when necessary.

### [1] First Embodiment

[1-1] Configuration of Inference System 1

In the present embodiment, an inference system using a multilayer neural network is assumed. In this inference system, a neural network is firstly established in a training stage. After the neural network is established, inference can be made as to what a new input is by using this neural network in the inference stage. In the description below, for example, an inference system will be described, where an input is an image in which any one of single-digit numerals 0 to 9 is drawn, and the inference system identifies the drawn numerals.

FIG. 1 is a block diagram illustrating a schematic configuration of an inference system 1. The inference system 1 includes a sensor 2, a training device 3, an inference device 4, and an application unit 5.

For example, the sensor 2 is an image sensor, and generates input data corresponding to the image from the image in which the numeral is drawn. As shown in the figure, the input data is constituted by (n+1) pixels, and the value Ak of each pixel is a digital value of one or multiple bits.

The training device 3 learns (or trains) features from many pieces of the input data generated by the sensor 2, to establish a neural network. As described later in detail, the established neural network is represented as weight coefficients used by arithmetic units in the inference device 4. When the training device 3 receives input data corresponding to the image in which a numeral “x” is drawn, the training device 3 finds weight coefficients for outputting that the input data is “x”.

By receiving numerous input data from a user of the inference system 1, the accuracy of the neural network can be improved, and the cost for collecting the data can be reduced. In the present embodiment, the training device 3 establishes the neural network using a known manner.

The inference device 4 obtains the weight coefficients of the neural network from the training device 3. When the training device 3 updates the neural network, the inference device 4 obtains the weight coefficients of a new neural network, thus improving the accuracy of the inference. Then, the inference device 4 having obtained the weight coefficients receives input data which are the inference targets generated by the sensor 2. Then, the inference device 4 applies the neural network using the weight coefficient on the input data, and identifies what the numeral drawn on the image is.

The application unit 5 performs various kinds of processing using the inference result.

Once the parameter of the neural network is obtained from the training device 3, the inference device 4 thereafter can identify the input data without referring to the training device 3, and the result of the inference is used by the application unit 5. For this reason, in the inference stage, this inference system 1 can operate with an extremely low power consumption.

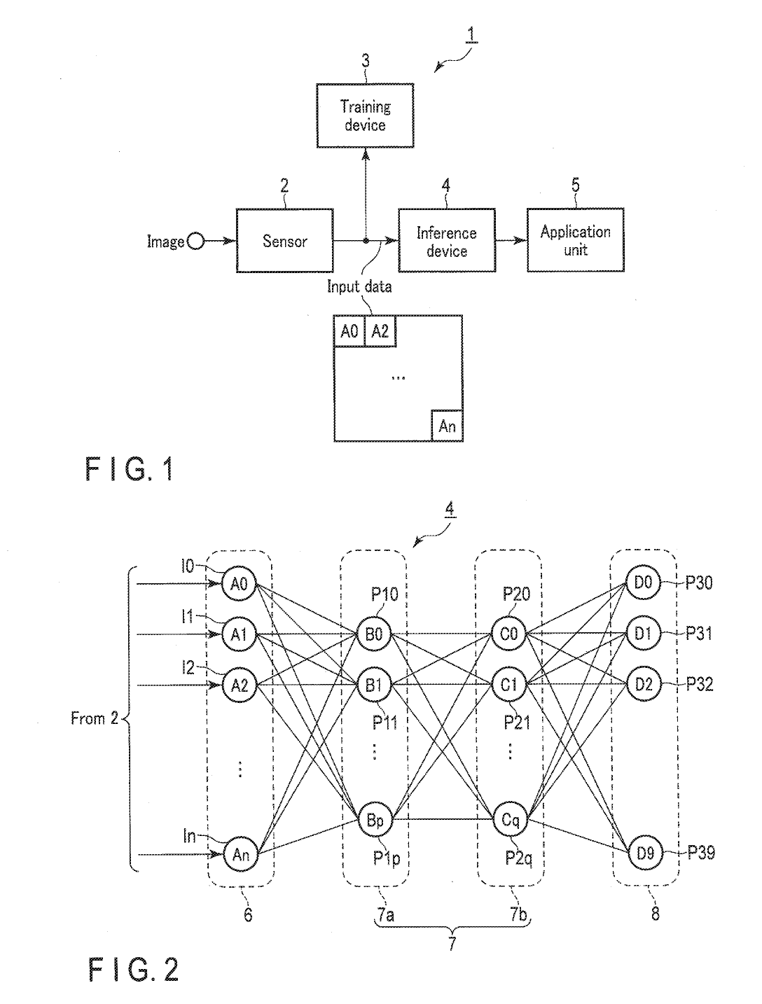

FIG. 2 is a block diagram illustrating a schematic configuration of the inference device 4 shown in FIG. 1, and illustrates the configuration applied with a neural network. The inference device 4 may be implemented with, for example, one or more integrated circuits. The inference device 4 includes an input layer 6, one or more hidden layers 7, and an output layer 8. The hidden layer 7 and output layer 8 are also collectively referred to as an arithmetic layer. FIG. 2 shows an example where the inference device 4 includes two hidden layers 7a, 7b. In this case, the hidden layer 7a is also referred to as the hidden layer of the first stage. The hidden layer 7b may also be referred to as a hidden layer subsequent to the hidden layer 7a of the previous stage, or as the hidden layer of the final stage.

The input layer 6 includes (n+1) input units I0 to In. The number (n+1) of input units I0 to In is equal to the number of pixels of the input data generated by the sensor 2. The k-th pixel value Ak of the input data is set in the input unit Ik.

The hidden layer 7a includes (p+1) arithmetic units P10 to P1p. p is any given integer of 1 or more. The operation of the arithmetic units P10 to P1p is all the same, and therefore, in the description below, they are described as the arithmetic unit P1k representing them. The arithmetic unit P1k receives (n+1) pixel values A0 to An from input units I0 to In of the input layer 6. Then, the arithmetic unit P1k performs predetermined arithmetic processing on the pixel values A0 to An and weight coefficients Fk0 to Fkn corresponding thereto respectively, thus generating a new digital value Bk. The digital value Bk may be one bit or multiple bits. The weight coefficients Fk0 to Fkn are obtained from the training device 3.

The hidden layer 7b has (q+1) arithmetic units P20 to P2q. q is any given integer of 1 or more. The operation of the arithmetic units P20 to P2p is all the same, and therefore, in the description below, they are described as the arithmetic unit P2k representing them. The arithmetic unit P2k receives (p+1) digital values B0 to Bp from the arithmetic units P10 to P1p of the hidden layer 7a of the previous layer. Then, the arithmetic unit P2k performs predetermined arithmetic processing on the digital values B0 to Bp and weight coefficients Gk0 to Gkp corresponding thereto respectively, thus generating a new digital value Ck. The digital value Ck may be one bit or multiple bits. The weight coefficients Gk0 to Gkp are obtained from the training device 3.

The output layer 8 has ten computation units P30 to P39, for example. In the present embodiment, the number of possible inference results is 10 (that is, one-digit numerals 0 to 9), and therefore, the arithmetic units P30 to P39 corresponding thereto are provided. The operation of the arithmetic units P30 to P39 is all the same, and therefore, in the description below, they are described as the arithmetic, unit P3k representing them. The arithmetic unit P3k receives (q+1) digital values C0 to Cq from the arithmetic units P20 to P2q of the hidden layer 7b. Then, the arithmetic unit P3k performs predetermined arithmetic processing on the digital values C0 to Cq and eight coefficients Hk0 to Hkq corresponding thereto respectively, thus generating a new digital value Dk. The weight coefficients Hk0 to Hkn are obtained from the training device 3.

Preferably, digital value Dk is one bit, and any one of digital values D0 to D9 is “1”. Then, for example, when the digital value D6 is “1”, the inference result is that, in the image, a numeral “6” is drawn.

In this case, the weight coefficients Fk0 to Fkn, Gk0 to Gkp and Hk0 to Hkq are important parameters in the neural network, and by appropriately defining them, the input data can be correctly identified.

FIG. 2 shows an example where the neural network has two hidden layers, but one or more hidden layers 7 may be additionally provided between the hidden layers 7a and 7b. In general, the larger the number of hidden layers is, the higher the accuracy of the inference becomes. Especially, defining weight coefficients with regard to many hidden layers is referred to as “deep learning”. Alternatively, there may be only one hidden layer. In this case, the hidden layer 7b is not provided, and the output of the hidden layer 7a is input into the output layer 8.

[1-2] Configuration of Arithmetic Device 7

In the present embodiment, the arithmetic processing of the hidden layer 7 is performed with hardware. In the following, the hidden layer 7 configured by hardware is called an arithmetic device 7.

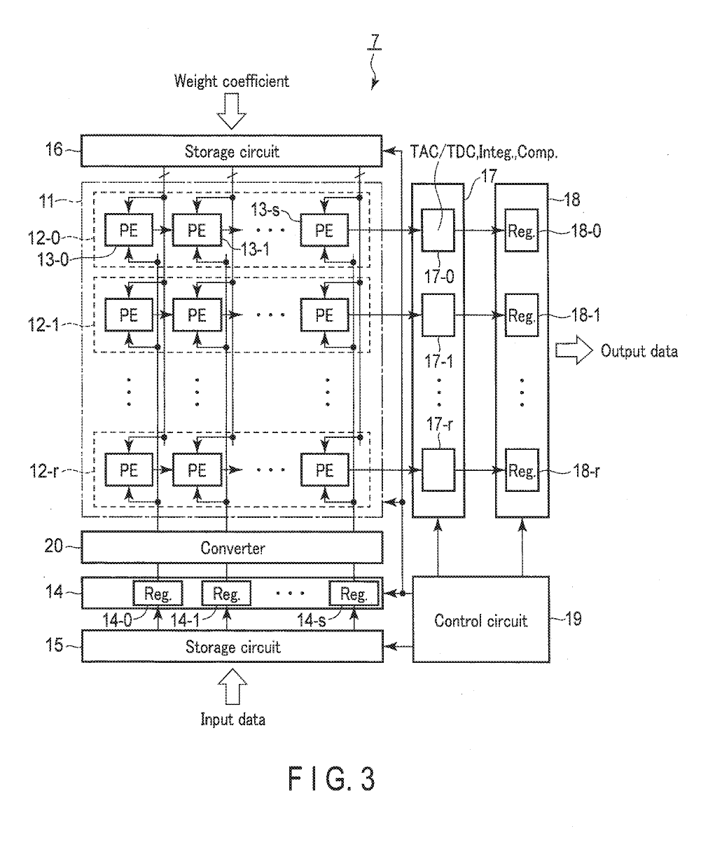

FIG. 3 is a block diagram of the arithmetic device 7 according to the present embodiment. The arithmetic device 7 includes an arithmetic element array 11, a register group 14 for input data, storage circuit 15 for input data, a converter 20, a storage circuit 16 for weight coefficient, a functional circuit group 17, a register group 18 for output data, and a control circuit 19.

The arithmetic element array 11 includes a plurality of arithmetic units (arithmetic circuits) 12-0 to 12-r aligned in a vertical direction. r is any integer of 1 or more. The arithmetic unit 12 performs a product-sum operation. The arithmetic unit 12 is also called a product-sum operation unit (multiply and accumulate unit (MAC unit)). The arithmetic unit 12 includes a plurality of arithmetic elements (processing element (PE)) 13-0 to 13-s connected in series. s is any integer. Specific configurations of the arithmetic unit 12 and the arithmetic element 13 will be described later.

The storage circuit 15 for input data receives input data sent from an input layer 6 or the arithmetic device (hidden layer) 7 (see FIG. 2) which is a device of the preprocessing stage, and stores this input data.

The register group 14 for input data includes a plurality of registers (Reg.) 14-0 to 14-s. The plurality of registers 14-0 to 14-s are provided to correspond to a plurality of arithmetic elements 13-0 to 13-s, respectively. The register group 14 temporarily holds the input data sent from the storage circuit 15. The register group 14 can temporarily old at least (s+1)-bit input data.

The converter 20 converts the input data input from the register group 14 to input data suitable for a circuit configuration of the arithmetic unit 12. A specific configuration of the converter 20 will be described later.

The storage circuit 16 for weight coefficient stores weight coefficients sent from the training device 3. The weight coefficients stored in the storage circuit 16 are set to the arithmetic element array 11.

The functional circuit group 17 includes a plurality of functional circuits 17-0 to 17-r. The plurality of functional circuits 17-0 to 17-r are provided to correspond to the arithmetic units 12-0 to 12-r. Each functional circuit 17 includes a time-to-analog converter (TAC), or a time-to-digital converter (TDC), and an integrator (Integ.) and a comparator (Comp.). The functional circuit 17 in FIG. 3 expresses a plurality of functional elements collectively for convenience sake, and its specific configuration will be described later.

The register group 18 for output data includes a plurality of registers (Reg.) 18-0 to 18-r. The plurality of registers 18-0 to 18-r are provided to correspond to the arithmetic units 12-0 to 12-r. The register group 18 temporarily holds output data sent from the functional circuit group 17. The register group 18 can temporarily hold at least (r+1)-bit output data.

The control circuit 19 integrally controls the operation of the arithmetic device 7. The control circuit 19 supplies various control signals to the arithmetic element array 11, the register group 14, the storage circuit 15, the storage circuit 16, the functional circuit group 17, and the register group 18.

[1-2-1] Configurations of Arithmetic Unit 12 and Functional Circuit 17

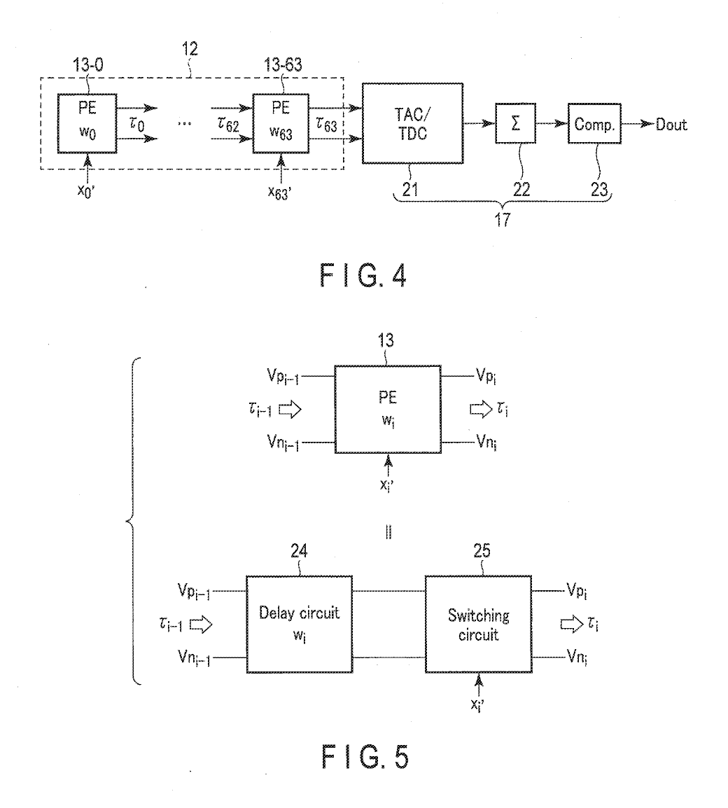

FIG. 4 is a block diagram for illustrating one arithmetic unit 12 and one functional circuit 17 shown in FIG. 3.

The arithmetic unit 12 includes, for example, 64 arithmetic elements 13-0 to 13-63. Weight coefficients w₀ to w₆₃ are set to the arithmetic elements 13-0 to 13-63, respectively. The arithmetic elements 13-0 to 13-63 receive input data x₀′ to x₆₃′ from the converter 20, respectively. The arithmetic elements 13-0 to 13-63 output delay time signals τ₀ to τ₆₃, respectively. The arithmetic elements 13-0 to 13-63 are connected in series, and a delay time signal output from any first arithmetic element 13-i is input into a second arithmetic element 13-(i+1) of the subsequent stage to this first arithmetic element 13-i. A delay time signal τ corresponds to a time difference of a differential output consisting of a first time signal and a second time signal.

The functional circuit 17 includes a TAC (or TDC) 21, an integrator 22, and a comparator 23. In the first embodiment, a configuration example of the TAC 21 will be described.

The TAC 21 converts a delay time calculated by the arithmetic unit 12 to a voltage signal (analog signal).

The integrator 22 integrates a plurality of output signals (voltage signals) output from the TAC 21. Integration in the present embodiment means to sequentially add a plurality of signals which are successively input.

The comparator 23 compares a voltage signal integrated by the integrator 22 with a reference voltage. If the voltage signal is higher than the reference voltage, it is determined to be data “1”, and if the voltage signal is equal to or less than the reference voltage, it is determined to be data “0”. Then, the comparator 23 outputs a comparison result as output data Dout.

Specific circuit configurations of the TAC 21, the integrator 22, and the comparator 23 will be described later.

[1-2-2] Configuration of Arithmetic Element 13

FIG. 5 is a block diagram of the arithmetic element 13 shown in FIG. 4. FIG. 5 illustrates any i-th arithmetic element 13. This arithmetic element 13 is a circuit example of a case where input data xᵢ′ is one bit. The arithmetic element 13 includes a delay circuit 24 and a switching circuit 25.

A first time signal Vpᵢ₋₁ and a second time signal Vnᵢ₋₁ are input into the delay circuit 24. The first time signal Vpᵢ₋₁ and the second time signal Vnᵢ₋₁ are voltage signals changing between high level (power supply voltage VDD) and low level (ground voltage VSS). A time difference between the first time signal Vpᵢ₋₁ and the second time signal Vnᵢ₋₁ is a delay time signal τᵢ₋₁.

The delay circuit 24 has a weight coefficient wᵢ. The delay circuit 24 uses the weight coefficient wᵢ to delay the second time signal Vnᵢ₋₁ by a time corresponding to the delay time signal τᵢ₋₁ from the first time signal Vpᵢ₋₁.

The switching circuit 25 receives two time signals from the delay circuit 24, and receives the input data xᵢ′. The switching circuit 25 can switch paths of the two time signals from the delay circuit 24 by using the input data xᵢ′. The switching circuit 25 outputs a third time signal Vpᵢ and a fourth time signal Vnᵢ. A time difference between the third time signal Vpᵢ and the fourth time signal Vnᵢ is a delay time signal τᵢ.

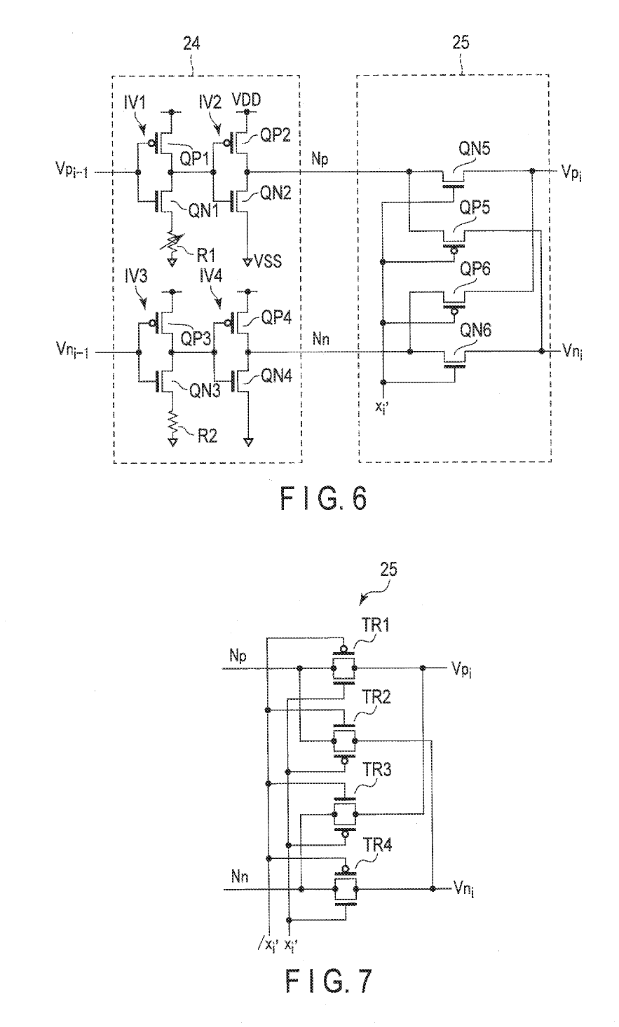

FIG. 6 is a circuit diagram of the delay circuit 24 and the switching circuit 25 shown in FIG. 5.

The delay circuit 24 includes four inverter circuits IV1 to IV4, a variable resistance element R1, and a resistance element R2. The four inverter circuits IV1 to IV4 each functions as a delay element.

Two inverter circuits IV1 and IV2 are connected in series between a signal line into which the first time signal Vpᵢ₋₁ is input, and a node Np.

The inverter circuit IV1 includes a PMOS transistor QP1 and an NMOS transistor QN1 connected in series. A source of the PMOS transistor QP1 is connected to a power supply terminal to which the power supply voltage VDD is supplied, and the first time signal Vpᵢ₋₁ is input into a gate of the PMOS transistor QP1. A gate of the NMOS transistor QN1 is connected to the gate of the PMOS transistor QP1, and a source of the NMOS transistor QN1 is connected to a ground terminal to which the ground voltage VSS is supplied via the variable resistance element R1. A resistance value of the variable resistance element R1 is set so as to delay by a time corresponding to the weight coefficient wᵢ.

The inverter circuit IV2 includes a PMOS transistor QP2 and an NMOS transistor QN2 connected in series. A source of the PMOS transistor QP2 is connected to the power supply terminal VDD, and a gate thereof is connected to a drain of the PMOS transistor QP1. A gate of the NMOS transistor QN2 is connected to a gate of the PMOS transistor QP2, and a source thereof is connected to the ground terminal VSS.

Two inverter circuits IV3 and IV4 are connected in series between a signal line into which the second time signal Vnᵢ₋₁ is input, and a node Nn.

The inverter circuit IV3 includes a PMOS transistor QP3 and an NMOS transistor QN3 connected in series. The resistance element R2 is connected to the NMOS transistor QN3. The inverter circuit IV4 includes a PMOS transistor QP4 and an NMOS transistor QN4 connected in series. Connection relationships between the transistors included in the inverter circuits IV3 and IV4 are the same as those of the inverter circuits IV1 and IV2.

The switching circuit 25 includes two NMOS transistors QN5 and QN6, and two PMOS transistors QP5 and QP6.

One end of the NMOS transistor QN5 is connected to the node Np, the other end thereof is connected to a signal line outputting the third time signal Vpᵢ, and the input data xᵢ′ is input into its gate. One end of the PMOS transistor QP5 is connected to the node Np, the other end is connected to a signal line outputting the fourth time signal Vnᵢ, and the input data xᵢ′ is input into its gate.

One end of the PMOS transistor QP6 is connected to the node Nn, the other end thereof is connected to a signal line outputting the third time signal Vpᵢ, and the input data xᵢ′ is input into its gate. One end of the NMOS transistor QN6 is connected to the node Nn, the other end is connected to a signal line outputting the fourth time signal Vnᵢ, and the input data xᵢ′ is input into its gate.

Namely, if the input data xᵢ′ is data “1,” the switching circuit 25 outputs a signal of the node Np as the third time signal Vpᵢ, and outputs a signal of the node Nn as the fourth time signal Vnᵢ. In addition, if the input data xᵢ′ is data “0,” the switching circuit 25 outputs a signal of the node Np as the fourth time signal Vnᵢ, and outputs a signal of the node Nn as the third time signal Vpᵢ.

The configuration of the arithmetic element 13 is not limited to the configurations of FIGS. 5 and 6, and other arithmetic elements that can delay a time signal can be used.

FIG. 7 is a circuit diagram illustrating another configuration example of the switching circuit 25. The switching circuit 25 includes four transfer gates TR1 to TR4. Each of the transfer gates TR1 to TR4 includes a PMOS transistor and an NMOS transistor connected in parallel.

One end of the transfer gate TR1 is connected to the node Np, and the other end thereof is connected to a signal line outputting the third time signal Vpᵢ. The input data xᵢ′ and /xᵢ′ are input into a gate of the NMOS transistor and a gate of the PMOS transistor of the transfer gate TR1, respectively. “/” means an inversion signal.

One end of the transfer gate TR2 is connected to the node Np, and the other end thereof is connected to a signal line outputting the fourth time signal Vnᵢ. The input data xᵢ′ and /xᵢ′ are input into a gate of the PMOS transistor and a gate of the NMOS transistor of the transfer gate TR2, respectively.

One end of the transfer gate TR3 is connected to the node Nn, and the other end thereof is connected to a signal line outputting the third time signal Vpᵢ. The input data xᵢ′ and /xᵢ′ are input into a gate of the PMOS transistor and a gate of the NMOS transistor of the transfer gate TR3, respectively.

One end of the transfer gate TR4 is connected to the node Nn, and the other end thereof is connected to a signal line outputting the fourth time signal Vnᵢ. The input data xᵢ′ and /xᵢ′ are input into a gate of the NMOS transistor and a gate of the PMOS transistor of the transfer gate TR4, respectively.

[1-2-3] Configuration of Converter 20

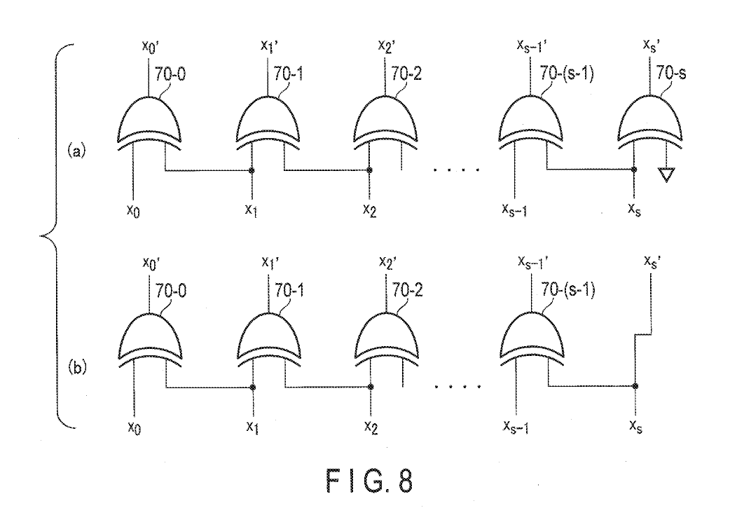

Next, a configuration of a converter 20 will be described. FIG. 8 is a circuit diagram of the converter 20 shown in FIG. 3. FIG. 8 illustrates the converter 20 according to two examples (FIG. 8(a) and FIG. 8(b)).

As shown in FIG. 8(a), the converter 20 receives (s+1)-bit input data x from the register group 14. The converter 20 converts the (s+1)-bit input data x (x₀ to xₛ) into (s+1)-bit input data x″ (x₀′ to xₛ′). The converter 20 in FIG. 8(a) includes (s+1) XOR circuits 70-0 to 70-s. The XOR circuit 70-0 generates the input data x₀′ according to an XOR operation of the input data x₀ and xᵢ. That is, an i-th XOR circuit 70-i generates the input data xᵢ′ according to the XOR operation of input data xᵢ and xᵢ₊₁, and outputs the generated input data xᵢ′ to the switching circuit 25-i of the arithmetic element 13-i. An arithmetic operation of the input data xₛ and data “0” is performed in the XOR circuit 70-s that generates xₛ′ corresponding to the least significant bit.

As illustrated in FIG. 8(b), when data “0” and the input data xₛ are input into the XOR circuit, an output xₛ′ of the XOR circuit is equal to the input data xₛ. Therefore, the input data xₛ may be directly used as the input data xₛ′, without using the XOR circuit 70-s.

Note that if the arithmetic element 13 is not differential, the converter 20 is unnecessary.

[1-2-4] Configurations of TAC 21, Integrator 22, and Comparator 23

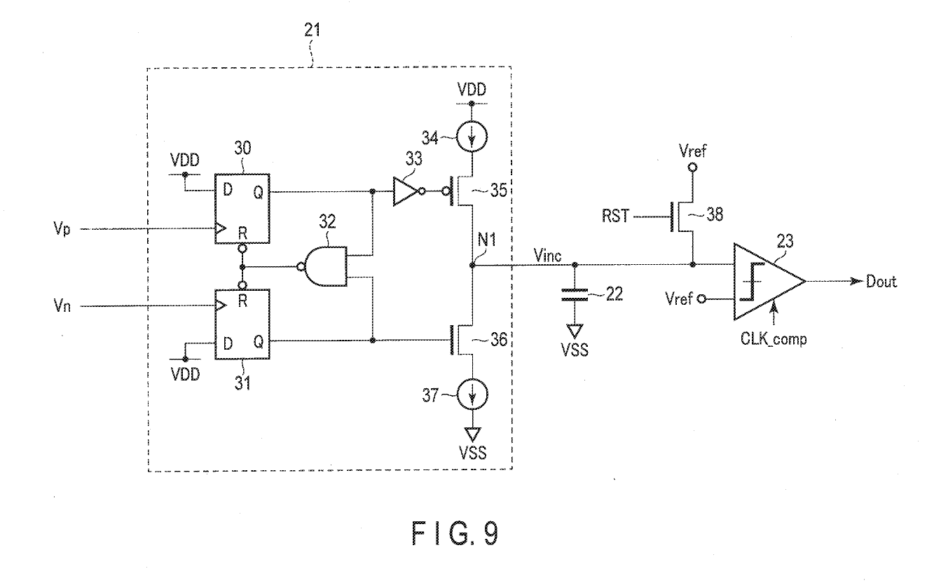

Next, specific configurations of the TAC 21, the integrator 22, and the comparator 23 will be described. FIG. 9 is a circuit diagram of the TAC 21, the integrator 22, and the comparator 23.

The TAC 21 includes flip-flops (D flip-flop) 30 and 31, a NAND gate 32, an inverter circuit 33, constant current sources 34 and 37, a PMOS transistor 35, and an NMOS transistor 36.

An input terminal D of the flip-flop 30 is connected to the power supply terminal VDD, and the first time signal Vp (i.e., the first time signal Vp of the final-stage arithmetic element 13-S included in the arithmetic unit 12) from the arithmetic unit 12 is input into a clock terminal of the flip-flop 30. If the first time signal Vp is high level, the flip-flop 30 outputs high level (voltage VDD) from an output terminal Q.

An input terminal D of the flip flop 31 is connected to the power supply terminal VDD, and the second time signal Vn (i.e., the second time signal Vn from the final-stage arithmetic element 13-S included in the arithmetic unit 12) from the arithmetic unit 12 is input into a clock terminal of the flip-flop 31. If the second time signal Vn is high level, the flip-flop 31 outputs high level (voltage VDD) from an output terminal Q.

A first input terminal of a NAND gate 32 is connected to the output terminal Q of the flip-flop 30, and a second input terminal of the NAND gate 32 is connected to the output terminal Q of the flip-flop 31. An output terminal of the NAND gate 32 is connected to reset terminals R of the flip-flops 30 and 31. If outputs of the flip-flops 30 and 31 are both high level, the NAND gate 32 outputs low level to reset the flip-flops 30 and 31.

An input terminal of the inverter circuit 33 is connected to the output terminal Q of the flip-flop 30. A source of the PMOS transistor 35 is connected to the constant current source 34, a drain thereof is connected to a node N1, and a gate thereof is connected to an output terminal of the inverter circuit 33.

A drain of the NMOS transistor 36 is connected to the node N1, a source thereof is connected to the constant current source 37, and a gate thereof is connected to the output terminal Q of the flip-flop 31. The TAC 21 outputs a voltage Vinc from the node N1.

The integrator 22 includes a capacitor 22. A first electrode of the capacitor 22 is connected to the node N1, and a second electrode thereof is connected to the ground terminal VSS.

A first input terminal of the comparator 23 is connected to the node N1, a second input terminal thereof is connected to a power supply terminal to which a reference voltage Vref is supplied, and a signal CLK_comp is input into a control terminal thereof from the control circuit 19. The reference voltage Vref has a relationship of “VDD>Vref≥VSS”. The reference voltage Vref can be discretionarily set, e.g., VDD/2. When the signal CLK_comp is asserted, the comparator 23 outputs a comparison result as the output data Dout.

In addition, a reset circuit 38 is connected to the node N1. The reset circuit 38 includes an NMOS transistor 38. A drain of the NMOS transistor 38 is connected to a power supply terminal Vref, a source thereof is connected to the node N1, and a reset signal RST is input into a gate thereof from the control circuit 19. The reset circuit 38 resets the voltage Vinc of the node N1 to the reference voltage Vref.

[1-3] Operation of Arithmetic Device 7

Now, an operation of the arithmetic device 7 configured like the above will be described.

[1-3-1] Overall Flow of Product-Sum Operation

The arithmetic device 7 divides a product-sum operation corresponding to a one-layered neural network into j repetitions (j is an integer of 1 or more) of product-sum operations, and executes the product-sum operations. The arithmetic device 7 also executes j repetitions (j is an integer of 1 or more) of product-sum operations per arithmetic unit 12. The arithmetic device 7 then sequentially integrates arithmetic results of j repetitions of product-sum operations, and upon completion of all the j repetitions of product-sum operations, outputs output data based on integration results. Each of the j repetitions of product-sum operations P is expressed by the following Equation (1):

P=Σ(wᵢ*xᵢ) (1)

x is input data, and w is a weight coefficient, e.g., i=0 to 63. Σ means a total sum of i=0 to 63. As described above, the input data directly input into the switching circuit 25-i is input data xᵢ′ which the input data xᵢ converted by the converter 20, but the arithmetic unit 12 can perform an arithmetic operation corresponding to Equation (1).

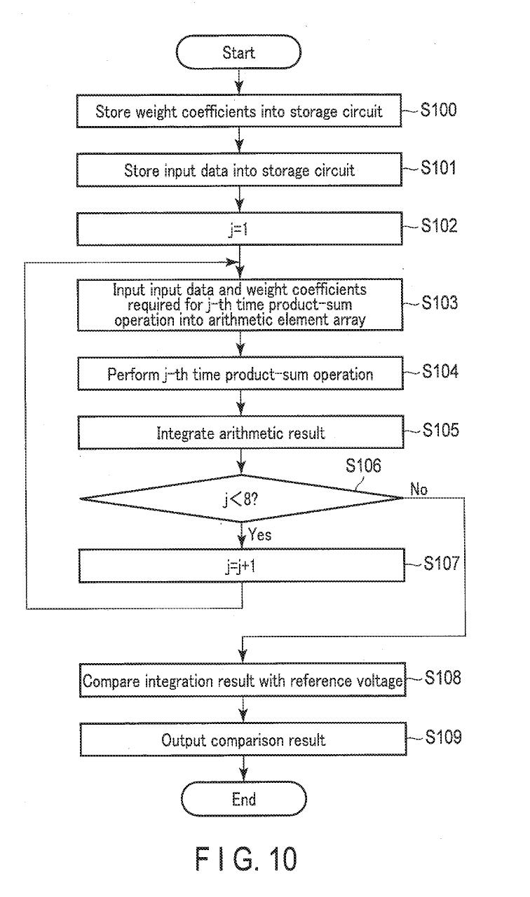

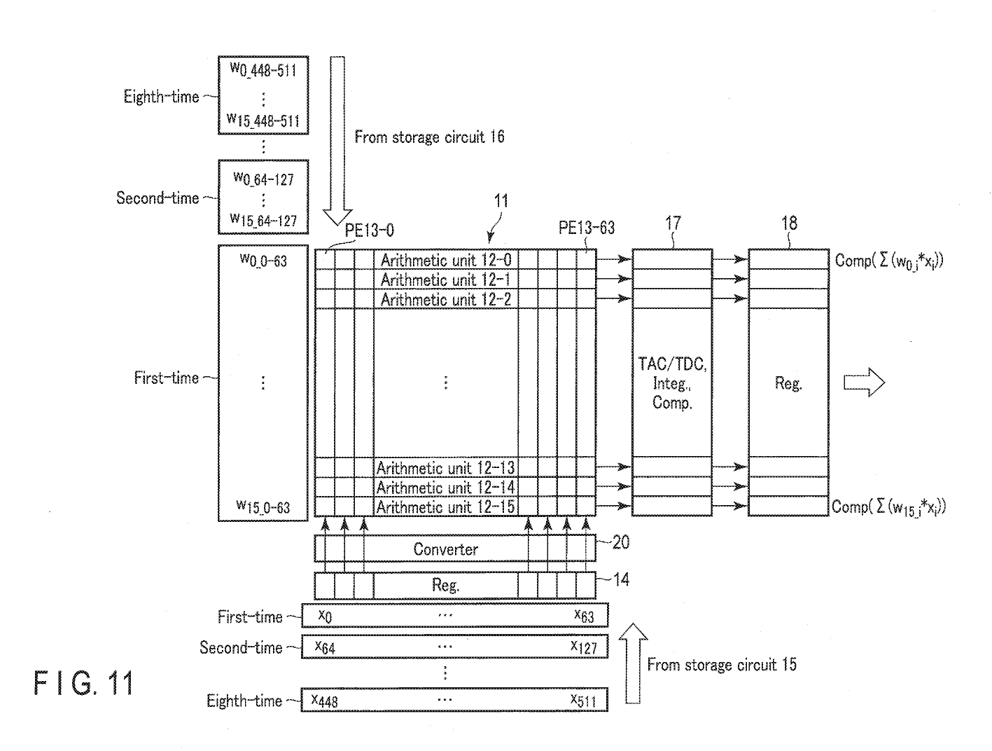

FIG. 10 is a flowchart for illustrating the product-sum operation of the arithmetic device 7. FIG. 11 is a schematic diagram for illustrating the product-sum operation of the arithmetic device 7. For example, it is assumed that the arithmetic unit 7 includes 16 arithmetic units 12-0 to 12-15, and each arithmetic unit 12 includes 64 arithmetic elements 13-0 to 13-63.

The control circuit 19 stores weight coefficients w into the storage circuit 16 (S100). In addition, the control circuit 19 stores input data x into the storage circuit 15 (S101). In an example of FIG. 11, input data x₀ to x₅₁₁ and weight coefficients w_{0_0} to w_{15_511} are shown. When each arithmetic unit 12 includes 64 arithmetic elements 13-0 to 13-63, 8 repetitions of product-sum operations corresponding to input data x₀ to x₆₃, x₆₄ to x₁₂₇, . . . , w₄₄₈ to x₅₁₁ are performed. In addition, when the arithmetic device 7 includes 16 arithmetic units 12-0 to 12-15, weight coefficients w_{0_0-63} to w_{15_0-63}, w_{0_64-127}, . . . , w_{0_448-511} to w_{15_448-511} are used for the 8 repetitions of product-sum operations, respectively.

Next, the control circuit 19 sets “j=1” for an internal counter (not shown in the drawings) (S102).

The control circuit 19 then inputs input data x and weight coefficients w required for the first-time product-sum operation into the arithmetic element array 11 (S103). Specifically, the control circuit 19 reads input data x₀ to x₆₃ among input data x₀ to x₅₁₁ stored in the storage circuit 15, and temporarily holds the input data x₀ to x₆₃ in the register group 14. The input data x₀ to x₆₃ held in the register group 14 are input into the arithmetic element array 11. In addition, the control circuit 19 reads weight coefficients w_{0_0-63} to w_{15_0-63} among the weight coefficients w_{0_0} to w_{15_511} stored in the storage circuit 16, and inputs the weight coefficients w_{0_0-63} to w_{15_0-63} into the arithmetic element array 11.

Subsequently, the arithmetic units 12-0 to 12-15 perform the first-time product-sum operation (S104).

Then, 16 integrator 22 corresponding to the arithmetic units 12-0 to 12-15 and included in the functional circuit 17 integrate arithmetic results of the arithmetic units 12-0 to 12-15, respectively (S105).

Next, the control circuit 19 determines if the number of repetitions of product-sum operations reaches a specified number of repetitions (8 repetitions in the present embodiment), i.e., if “j<8” or not (S106). If the number of repetitions of product-sum operations has not reached the specified number of repetitions (S106=Yes), the control circuit 19 sets “j=j+1” to the internal counter (S107). Subsequently, the control circuit 19 repeats processing of S103 and the subsequent processing.

If the number of repetitions of product-sum operations has reached the specified number of repetitions (S106=No), each of the 16 comparators 23 corresponding to the arithmetic units 12-0 to 12-15 and included in the functional circuit 17 compares an integration result by the integrator 22 with the reference voltage Vref (S108). Then, the 16 comparators 23 respectively output comparison results Comp(Σ(w_{0_i}*xᵢ)) to Comp(Σ(w_{15_i}*xᵢ)) as the output data Dout.

[1-3-2] Operation of TAC 21

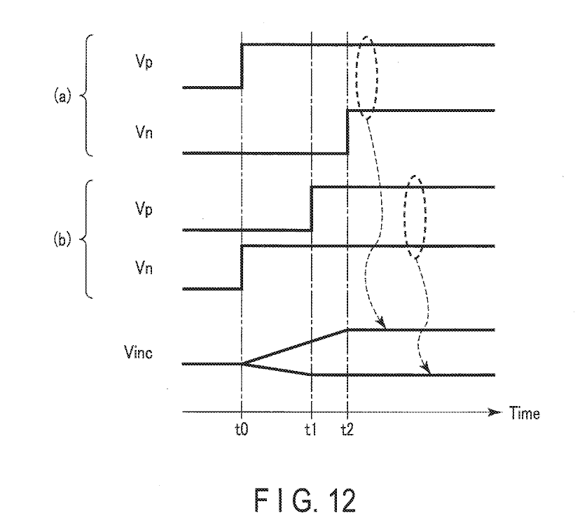

Next, an operation of the TAC 21 will be described. FIG. 12 is a timing diagram for illustrating the operation of the TAC 21.

The TAC 21 receives a first time signal Vp and a second time signal Vn from the arithmetic unit 12 corresponding to the TAC 21. FIG. 12 illustrates two examples (a) and (b). Example (a) is a case where the first time signal Vp is faster than the second time signal Vn, and example (b) is a case where the first time signal Vp is slower than the second time signal Vn.

In the example (a), at a time t0, the first time signal Vp changes from low level to high level. Accordingly, as shown in FIG. 9, the flip-flop 30 outputs high level, and the PMOS transistor 35 is turned on. Thus, the voltage Vinc increases. At a time t2, the second time signal Vn changes to high level. Then, the flip-flop 31 outputs high level, and the NAND gate 32 outputs low level. Thus, the flip-flops 30 and 31 are reset, and the PMOS transistor 35 is turned off. At the time t2 and after, a level of the voltage Vinc is maintained by the integrator 22.

In an example (b), at the time t0, the second time signal Vn changes to high level. Accordingly, as shown in FIG. 9, the flip-flop 31 outputs high level, and the NMOS transistor 36 is turned on. Thus, the voltage Vinc drops. At a time t1, the first time signal Vp changes to high level. Then, the flip-flop 30 outputs high level, and the NAND gate 32 outputs low level. Thereby, the flip-flops 30 and 31 are reset, and the NMOS transistor 36 is turned off. At the time t1 and after, the level of the voltage Vinc is maintained by the integrator 22.

In this way, the TAC 21 can convert the delay time τ which is a difference between the first time signal Vp and the second time signal Vn to an amplitude of a voltage signal.

[1-3-3] Details of Product-Sum Operation

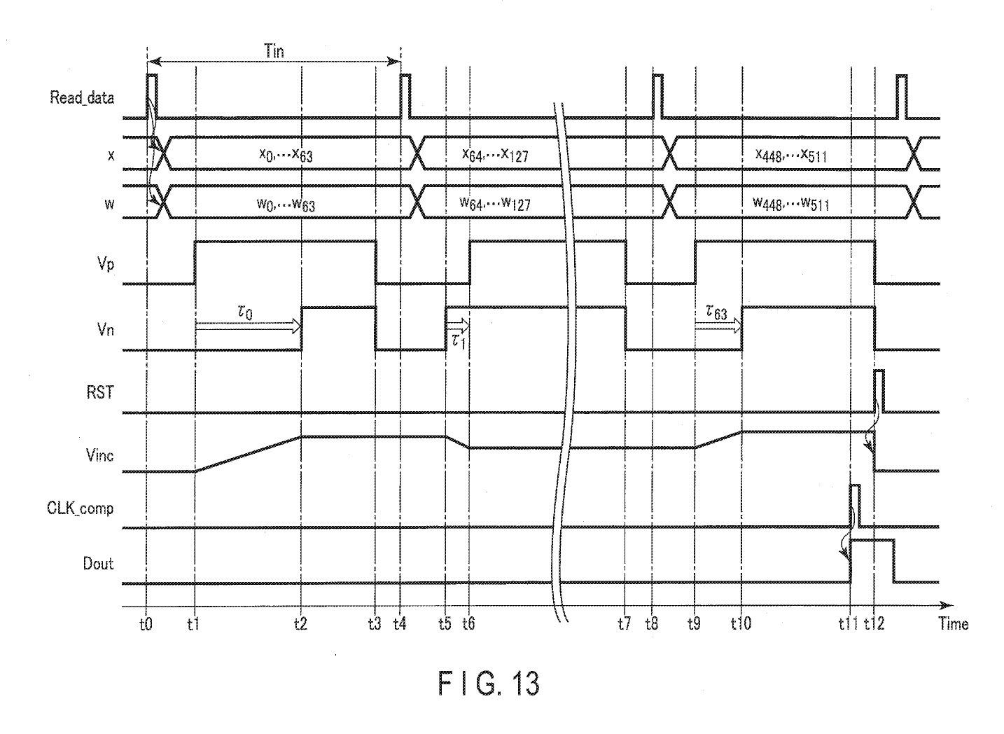

Now, details of a product-sum operation of the arithmetic device 7 will be described. FIG. 13 is a timing diagram for illustrating the product-sum operation of the arithmetic device 7. FIG. 13 illustrates an operation of a product-sum operation for one arithmetic unit 12.

At a time t0, the control circuit 19 sends a signal Read_data and an address specifying read target data to the storage circuits 15 and 16 for reading input data x₀ to x₆₃ and weight coefficients w₀ to w₆₃ required for the first-time product-sum operation from the storage circuits 15 and 16. The weight coefficients w₀ to w₆₃ represent weight coefficients used in one arithmetic unit 12, and row information is omitted. In response to the signal Read_data, the storage circuit 15 reads the input data x₀ to x₆₃, and sends them to the register group 14. The register group 14 sends the input data x₀ to x₆₃ to the arithmetic unit 12. In addition, in response to the signal Read_data, the storage circuit reads the weight coefficients w₀ to w₆₃, and sends them to the arithmetic unit 12.

The arithmetic unit 12 performs a product-sum operation using the input data x₀ to x₆₃ and the weight coefficients w₀ to w₆₃. Then, the arithmetic unit 12 outputs a delay signal τ₀ as the first time signal Vp and the second time signal Vn. In an example of FIG. 13, the first time signal Vp changes to high level at a time t1, and the second time signal Vn changes to high level at a time t2. The first-time product-sum operation ends, and a result of the first-time product-sum operation is integrated by the integrator 22, as the voltage Vinc. In addition, the flip-flops 30 and 31 of the TAC 21 are reset. At a time t3, Vp and Vn are reset to low level.

At a time t4, the control circuit 19 sends the signal Read_data and an address to the storage circuits 15 and 16 for reading input data x₆₄ to x₁₂₇ and weight coefficients w₆₄ to w₁₂₇ required for the second-time product-sum operation from the storage circuits 15 and 16. In response to the signal Read_data, the storage circuit 15 reads the input data x₆₄ to x₁₂₇. In addition, in response to the signal Read_data, the storage circuit 16 reads the weight coefficients w₆₄ to w₁₂₇. An interval Tin of two consecutive signals Read_data is appropriately set according to the number of the arithmetic elements 13 included in the arithmetic unit 12.

The arithmetic unit 12 performs a product-sum operation to output a delay signal τ₁ using the input data x₆₄ to x₁₂₇ and the weight coefficients w₆₄ to w₁₂₇. In the example of FIG. 13, the second time signal Vn changes to high level at a time t5, and the first time signal Vp changes to high level at a time t6. The second-time product-sum operation ends, and a result of the second-time product-sum operation is integrated by the integrator 22, as the voltage Vinc. Thereafter, the third to seventh-time product-sum operations will be repeated.

At a time t8, the control circuit 19 sends the signal Read_data and an address to the storage circuits 15 and 16 for reading input data x₄₄₈ x₅₁₁ and weight coefficients w₄₄₈ to w₅₁₁ required for the eighth-time product-sum operation. In response to the signal Read_data, the storage circuit 15 reads the input data x₄₄₈ to x₅₁₁. In addition, in response to the signal Read_data, the storage circuit 16 reads the weight coefficients w₄₄₈ to w₅₁₁.

The arithmetic unit 12 performs a product-sum operation to output a delay signal τ₆₃ by using the input data x₄₄₈ to x₅₁₁ and the weight coefficients w₄₄₈ to w₅₁₁. In the example of FIG. 13, the first time signal Vp changes to high level at a time t9, and the second time signal Vn changes to high level at a time t10. The eighth-time product-sum operation ends, and a result of the eighth-time product-sum operation is integrated by the integrator 22, as the voltage Vinc.

At a time t11, the control circuit 19 makes a signal CLK_comp to be high level. In response to the signal CLK_comp, the comparator 23 compares the voltage Vinc and the reference voltage Vref. The comparator 23 outputs a comparison result as the output data Dout. In the example of FIG. 13, data “1” is output as the output data Dout.

At a time t12, the control circuit 19 makes a reset signal RST to be high level. In response to the reset signal RST, the reset circuit 38 resets the voltage Vinc.

[1-4] Advantageous Effects of First Embodiment

As described above in detail, in the first embodiment, the arithmetic device 7 includes the arithmetic unit (arithmetic circuit) 12, the TAC 21, the integrator 22, and the comparator 23. The arithmetic unit 12 includes a plurality of arithmetic elements 13 connected in series, and sequentially performs multiple repetitions of product-sum operation processing. Each of the plurality of arithmetic elements 13 receives the first and second time signals Vpᵢ₋₁ and Vnᵢ₋₁, and generates and outputs the first and second time signals Vpᵢ and Vnᵢ which are the first and second time signals Vpᵢ₋₁ and Vnᵢ₋₁ which are delayed by a time corresponding to the weight coefficient w and the input data x. For every multiple repetition of arithmetic processing, the TAC 21 converts a difference between the first and second time signals Vp and Vn output from the arithmetic unit 12 to a voltage signal (analog signal). The integrator 22 integrates a plurality of voltage signals which were converted by the TAC 21. The comparator 23 compares an integration result by the integrator 22 with the reference voltage Vref, and outputs a comparison result as the output data Dout.

Thus, according to the first embodiment, a product-sum operation required for one-layered neural network can be performed by dividing the product-sum operation into multiple repetitions of product-sum operations by the arithmetic unit 12. Namely, a product-sum operation for one layer can be performed by using the arithmetic elements 13 fewer than the total number (the number of MACs) of product-sum operations. In the example of the present embodiment, 512 repetitions of product-sum operations corresponding the input data x₀ to x₅₁₁ can be performed by 64 arithmetic elements (PE) 13. Thereby, the upper limit of the product-sum operations does not depend on the number of PEs, and the number of PEs does not need to be matched with the maximum number of MACS of a multilayer neural network. As a result, a circuit area of the arithmetic device 7 can be reduced.

In addition, in a layer with the small number of MACs of a multilayer neural network, the speed of arithmetic processing can be increased.

### [2] Second Embodiment

In a second embodiment, the arithmetic device 7 is configured by using a TDC (time-to-digital converter) instead of the TAC used in the first embodiment.

[2-1] Configurations of TDC 21, Integrator 22, and Comparator 23

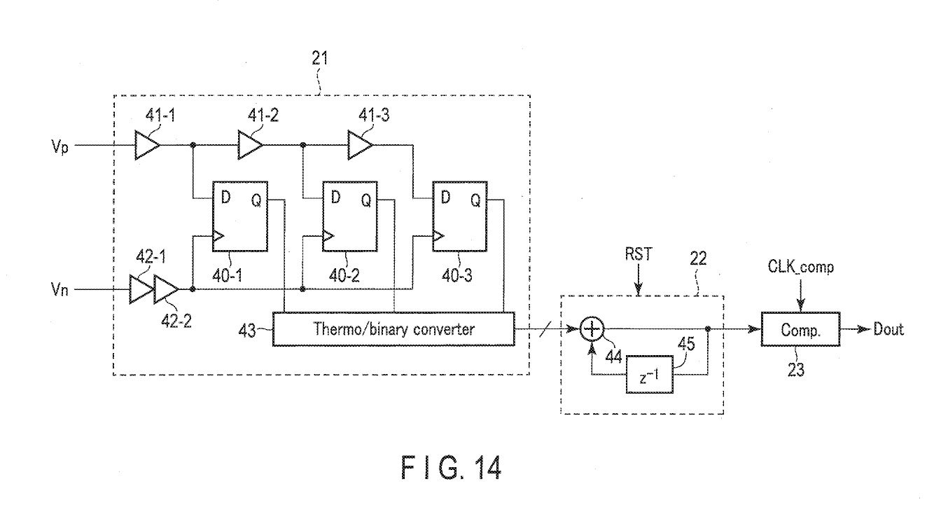

FIG. 14 is a circuit diagram of a TDC 21, the integrator 22, and the comparator 23 according to the second embodiment.

The TDC 21 includes a plurality of flip-flops (D flip-flops) 40. In FIG. 14, three flip-flops 40-1 to 40-3 are illustrated as an example. The number of flip-flops 40 can be discretionarily set. Furthermore, the TDC 21 includes delay elements 41-1 to 41-3 whose number corresponds to that of the flip-flops 40-1 to 40-3, and for example two delay elements 42-1 and 42-2 and a thereto/binary (thermometer-to-binary) converter 43.

Each of the delay elements 41-1 to 41-3, 42-1, and 42-2 delays an input signal by a predetermined time. The delay elements 41-1 to 41-3 are connected in series. Into an input terminal of the delay element 41-1, the first time signal Vp (i.e., the first time signal Vp of the final-stage arithmetic element 13 included in the arithmetic unit 12) of the arithmetic unit 12 is input. The delay elements 41-1 to 41-3 sequentially delay the first time signal Vp.

The delay elements 42-1 and 42-2 are connected in series into an input terminal of the delay element 42-1, the second time signal Vn (i.e., the second time signal Vn of the final-stage arithmetic element 13 included in the arithmetic unit 12) of the arithmetic unit 12 is input. The delay elements 42-1 and 42-2 delay the second time signal Vn by the same delay time as that of each of the delay elements 41-1 to 41-3.

An input terminal D of the flip-flop 40-1 is connected to an output terminal of the delay element 41-1, an output terminal thereof is connected to a thermo/binary converter 43, and a clock terminal thereof is connected to an output terminal of the delay element 42-2.

An input terminal D of the flip-flop 40-2 is connected to an output terminal of the delay element 41-2, an output terminal thereof is connected to the thermo/binary converter 43, and a clock terminal thereof is connected to an output terminal of the delay element 42-2.

An input terminal D of the flip-flop 40-3 is connected to an output terminal of the delay element 41-3, an output terminal thereof is connected to the thermo/binary converter 43, and a clock terminal thereof is connected to an output terminal of the delay element 42-2.

The thermo/binary converter 43 converts a thermometer code to a binary code. The thermo/binary converter 43 is a kind of A/D (analog to digital) converter. The thermometer code is a code so that data “1” sequentially increases from a least significant bit, like “0 . . . 0011 . . . 1”, and a degree of a numerical value can be expressed by the number of data “1”.

In the TDC 21 with the above configuration, each of the flip-flops 40-1 to 40-3 outputs an input signal at a timing when the second time signal Vn delayed by the delay elements 42-1 and 42-2 becomes high level. That is, the flip-flops 40-1 to 40-3 output the delay time τ, which is a difference between the first time signal Vp and the second time signal Vn, as a thermometer code. For example, with the thermometer code being a 3 bit value, when the first time signal Vp is faster than the second time signal Vn, the thermometer code is “011” or “111”, and when the second time signal Vn is faster than the first time signal Vp, the thermometer code is “000” or “001”.

The integrator 22 includes an adder 44 and a delay circuit (z⁻¹) 45. The adder 44 adds binary data output from the thermo/binary converter 43 and binary data output from the delay circuit 45. The delay circuit 45 delays the binary data output from the adder 44 by a predetermined time, and outputs the delayed binary data to the adder 44. Thereby, the adder 44 can output binary data in which a current arithmetic result is added to a previous arithmetic result.

In addition, the integrator 22 receives the reset signal RST from the control circuit 19. The integrator 22 resets an integration value when the reset signal RST is asserted.

The comparator 23 compares data output from the integrator 22 with reference data. Assuming an intermediate value between a thermometer code “001” and a thermometer code “011”, e.g. “1.5”, the reference data is set to 1.5*N. N is the number of repetitions of integration. By using the reference data “1.5*N”, in a case where eight repetitions of product-sum operations are performed, for example, it can be determined which of the first time signal Vp and the second time signal Vn, for which the eight repetitions of integrations were performed, is faster. The comparator 23 outputs a comparison result as the output data Dout.

[2-2] Operation of Arithmetic Device 7

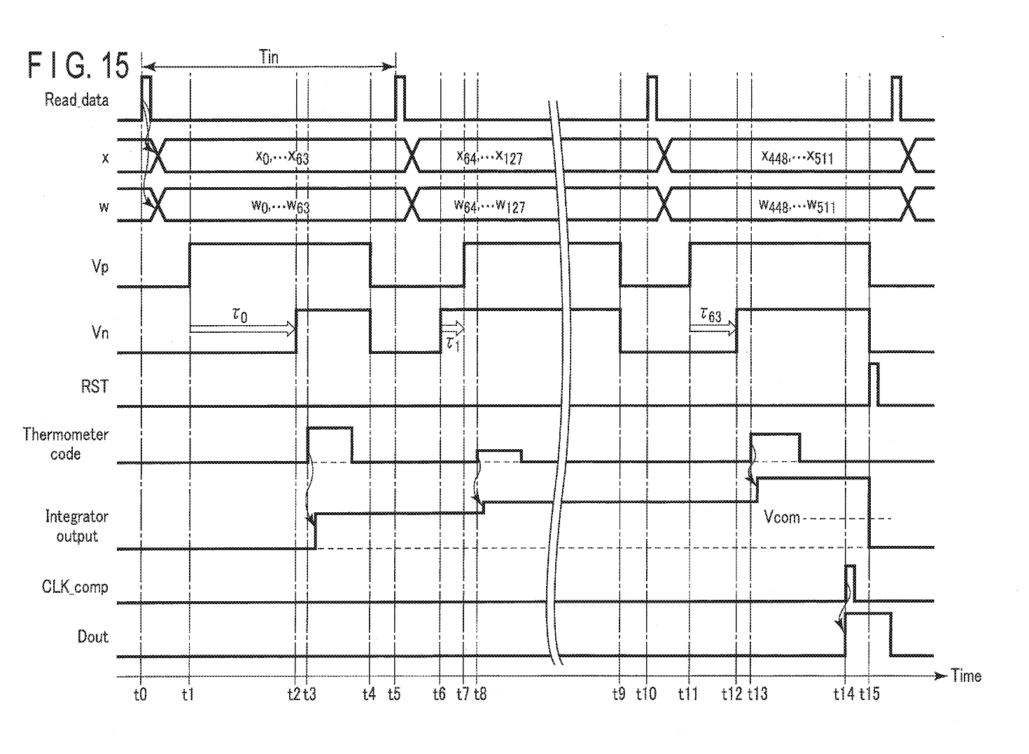

FIG. 15 is a timing diagram for illustrating a product-sum operation of the arithmetic device 7 according to the second embodiment. Waveforms of the signal Read_data, the input data x, the weight coefficient w, the first time signal Vp, and the second time signal Vn are the same as those of FIG. 13 for the first embodiment.

At a time t0, the input data x₀ to x₆₃ and the weight coefficients w₀ to x₆₃ for the first-time product-sum operation are input into the arithmetic unit 12. At a time t3, the TDC 21 generates a thermometer code as a result of the first-time product-sum operation. After that, the integrator 22 integrates binary data of the thermometer code.

At a time t8, the TDC 21 generates a thermometer code as a result of the second-time product-sum operation. The integrator 22 integrates binary data of the thermometer code.

At a time t13, the TDC 21 generates a thermometer code as a result of the eighth-time product-sum operation. The integrator 22 integrates binary data of the thermometer code.

At a time t14, the control circuit 19 makes the signal CLK_comp to be high level. In response to the signal CLK_comp, the comparator 23 compares an output of the integrator 22 with reference data Vcom. The integrator 23 outputs a comparison result as the output data Dout.

At a time t15, the control circuit 19 makes the reset signal RST to be high level. In response to the reset signal RST, the integrator 22 resets an integration value.

[2-3] Modification Example

The thermo/binary converter 43 may also output what is substantially negative binary data. A negative value can be expressed by using the complement of 2. Thereby, if the first time signal Vp is faster than the second time signal Vn, the integrator 22 can perform addition of the binary data, and if the first time signal Vp is slower than the second time signal Vn, the integrator 22 can perform subtraction of the binary data.

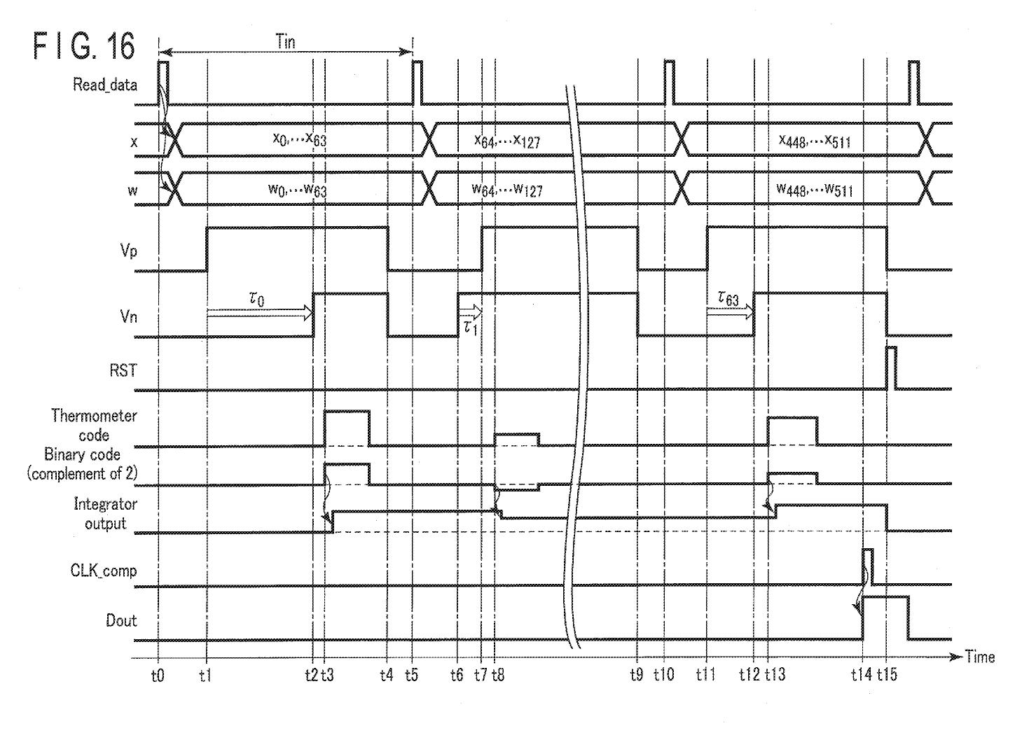

FIG. 16 is a timing diagram for illustrating a product-sum operation of the arithmetic device 7 according to a modification example.

In the second-time product-sum operation, the first time signal Vp is slower than the second time signal Vn. In this case, the thereto binary converter 43 outputs binary data expressing a negative value. Thus, an integration result by the integrator 22 becomes smaller than the previous integration result.

[2-4] Advantageous Effects of Second Embodiment

According to the second embodiment as described above in detail, it is possible to configure the arithmetic device 7 by using the TDC 21. Namely, by using a digital signal, results of multiple repetitions of product-sum operations can be integrated. The other advantageous effects of the second embodiment are the same as those of the first embodiment.

### [3] Third Embodiment

In the third embodiment, the arithmetic device 7 is configured with arithmetic elements (PE) 13 different from those of the first embodiment.

[3-1] Configuration of Arithmetic Unit 12

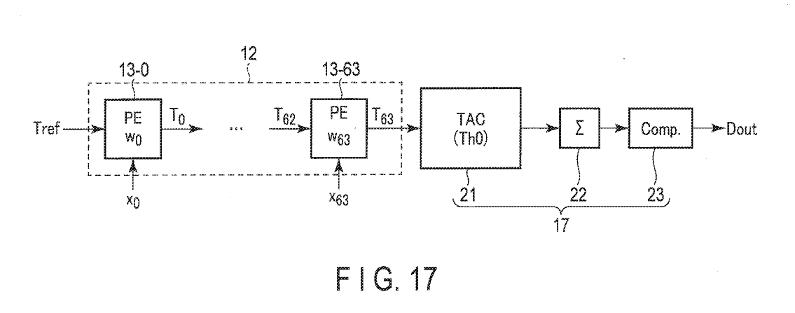

FIG. 17 is a block diagram for illustrating one arithmetic unit 12 and one functional circuit 17 according to the third embodiment. In the third embodiment, the converter 20 described in the first embodiment is unnecessary, and the input data x stored in the register group 14 is input into the arithmetic element array 11.

The arithmetic unit 12 includes, for example, 64 arithmetic elements 13-0 to 13-63. To the arithmetic elements 13-0 to 13-63, the weight coefficients w₀ to w₆₃ are set, respectively. The arithmetic elements 13-0 to 13-63 receive the input data x₀ to x₆₃ from the register group 14. Into the first-stage arithmetic element 13-0, a reference time signal Tref is input from the control circuit 19. The reference time signal Tref is a signal in which a voltage level changes at a certain reference time and in a predetermined cycle.

The arithmetic elements 13-0 to 13-63 perform a product-sum operation. The arithmetic elements 13-0 to 13-63 output time signals T₀ to T₆₃, respectively. The arithmetic elements 13-0 to 13-63 are connected in series, and a time signal output from any first arithmetic element 13 is input into the second arithmetic element 13 of the subsequent stage to this first arithmetic element 13.

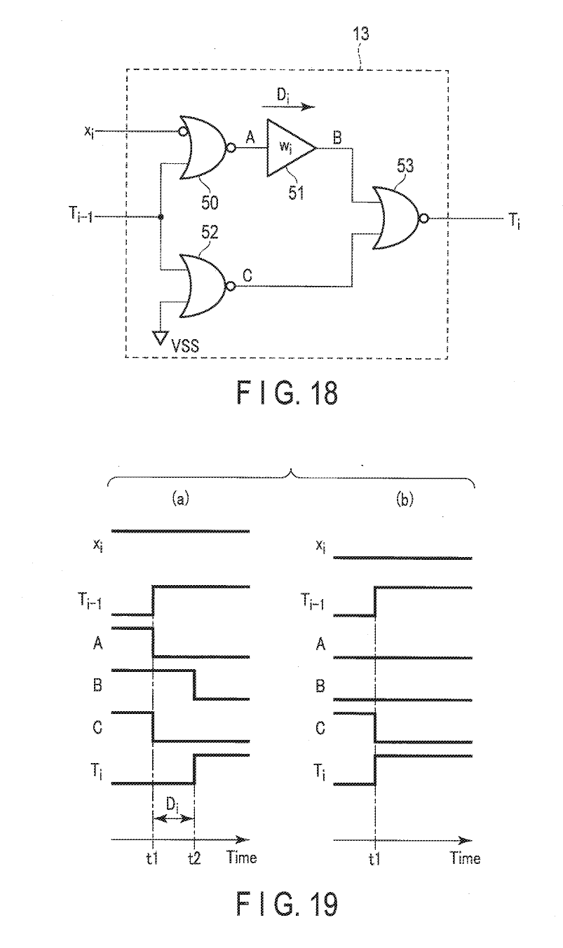

FIG. 18 is a circuit diagram of the arithmetic element 13 shown in FIG. 17. FIG. 18 illustrates any i-th arithmetic element 13. This arithmetic element 13 is a circuit example in a case where the input data xᵢ is one bit.

The arithmetic element 13 includes a NOR gate 50, a delay element 51, and NOR gates 52 and 53.

The NOR gate 50 generates a signal A by NOR operation of inversion of the input data xᵢ and a time signal Tᵢ₋₁. The delay element 51 delays the signal A by a time Dᵢ corresponding to a weight coefficient wᵢ to generate a signal B. In the NOR gate 52, one of the inputs is fixed at data“0”, and therefore, a signal C is generated by inversing the time signal Tᵢ₋₁. The NOR gate 53 generates a time signal Tᵢ by NOR operation of the signal B and a signal C.

FIG. 19 is a timing diagram for illustrating an operation of the arithmetic element 13 according to the third embodiment. FIG. 19(a) is a timing diagram in a case where the input data xᵢ is “1,” and FIG. 19(b) is a timing diagram in a case where the input data xᵢ is “0.” In the description below, unless otherwise specified, the delay time of the NOR gates 50, 52, and 53 is sufficiently smaller than the delay time of the delay element 51, and is therefore, disregarded.

It is assumed that the time signal Tᵢ₋₁ changes from low level to high level at the time t1. As shown in FIG. 19(a), when the input data xᵢ is “1”, the time signal Tᵢ is a signal that changes from “0” to “1” at the time t2 when the time Dᵢ corresponding to the weight coefficient wᵢ has elapsed since the time t1. That is, the time signal Tᵢ is a signal that is obtained by delaying the time signal Tᵢ₋₁ by the time Dᵢ.

On the other hand, as shown in FIG. 19(b), when the input data xᵢ is “0”, the time signal Tᵢ is a signal that changes from “0” to “1” at the time t1. That is, the time signal Tᵢ is the time signal Tᵢ₋₁ itself.

[3-2] Configurations of TAC 21, Integrator 22, and Comparator 23

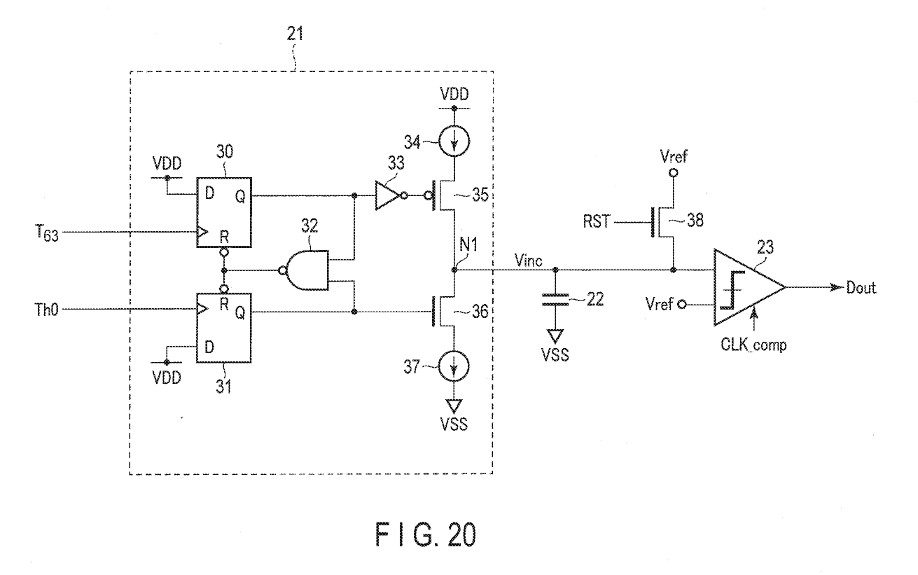

FIG. 20 is a circuit diagram of the TAC 21, the integrator 22, and the comparator 23 according to the third embodiment. In FIG. 20, signals input into the TAC 21 are different from those in FIG. 9 for the first embodiment.

Into a clock terminal of the flip-flop 30, the time signal T₆₃ is input from the final-stage arithmetic element 13-63 included in the arithmetic unit 12.

The control circuit 19 generates a time threshold value signal Th0, and supplies it to the TAC 21. The time threshold value signal Th0 is a voltage signal that changes between high level (power supply voltage VDD) and low level (ground voltage VSS). In addition, the time threshold value signal Th0 becomes high level at a certain reference time and in a predetermined cycle (timing). Into a clock terminal of the flip-flop 31, the time threshold value signal Th0 is input from the control circuit 19. The other configurations of the third embodiment are the same as those in FIG. 9 for the first embodiment.

The TAC 21 increases the voltage Vinc when the time signal T₆₃ is faster than the time threshold value signal Th0, and drops the voltage Vinc when the time signal T₆₃is slower than the time threshold value signal Th0.

[3-3] Operation of Arithmetic Device 7

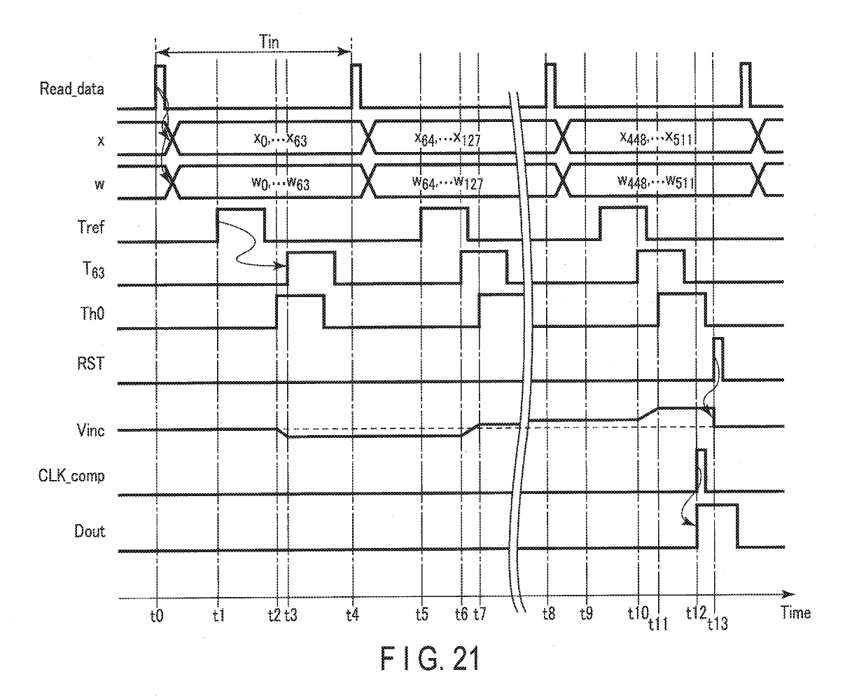

FIG. 21 is a timing diagram for illustrating a product-sum operation of the arithmetic device 7 according to the third embodiment. Waveforms of the signal Read_data, the input data x, and the weight coefficient w are the same as those in FIG. 13 for the first embodiment.

At a time t0, the input data x₀ to x₆₃ and the weight coefficients w₀ to w₆₃ for the first-time product-sum operation are input into the arithmetic unit 12. At a time t1, the control circuit 19 makes the reference time signal Tref to be high level. The reference time signal Tref is input into the first-stage arithmetic element 13-0 included in the arithmetic unit 12. The arithmetic unit 12 performs the first-time product-sum operation by using the reference time signal Tref.

At a time t2, the control circuit 19 makes the time threshold value signal Th0 to be high level. The time threshold value signal Th0 is input into the TAC 21, as the first-time product-sum operation. At a time t3, the final-stage arithmetic element 13-63 included in the arithmetic unit 12 makes the time signal T₆₃ to be high level. Then, a result of the first-time product-sum operation is integrated by the integrator 22, as the voltage Vinc.

At a time t4, the second-time product-sum operation is started. At a time t5, the reference time signal Tref becomes high level; at a time t6, the time signal T₆₃ becomes high level; and at a time t7, the time threshold value signal Th0 becomes high level as the second-time product-sum operation. Then, a result of the second-time product-sum operation is integrated by the integrator 22, as the voltage Vinc.

At a time t8, the eighth-time product-sum operation is started. At a time t9, the reference time signal Tref becomes high level; at a time t10, the time signal T₆₃ becomes high level; and at a time t11, the time threshold value signal Th0 becomes high level as the eighth-time product-sum operation. Then, a result of the eighth-time product-sum operation is integrated by the integrator 22, as the voltage Vinc.

At a time t12, the control circuit 19 makes the signal CLK_comp to be high level. In response to the signal CLK_comp, the comparator 23 compares the voltage Vinc with the reference voltage Vref. The comparator 23 outputs a comparison result as the output data Dout.

At a time t13, the control circuit 19 makes the reset signal RST to be high level. In response to the reset signal RST, the reset circuit 38 resets the voltage Vinc.

[3-4] Advantageous Effects of Third Embodiment

As described above in detail, in the third embodiment, a product-sum operation can be performed by using the arithmetic element 13 of single-phase input and single-phase output. The other advantageous effects of the third embodiment are the same those of the first embodiment.

It is also possible to apply the TDC of the second embodiment to the arithmetic device 7 of the third embodiment.

### [4] Fourth Embodiment

In a fourth embodiment, an interval Tin of the signal Read_data used for starting multiple repetitions of product-sum operations is variable.

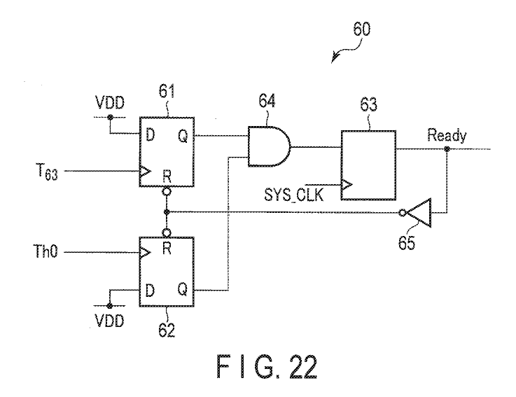

The arithmetic device 7 includes a signal generating circuit 60 generating a signal Ready for controlling a timing of the signal Read_data. FIG. 22 is a circuit diagram of the signal generating circuit 60 according to the fourth embodiment. Each of a plurality of lines of arithmetic units 12 is provided with one signal generating circuit 60.

The signal generating circuit 60 includes flip-flops 61 to 63, an AND gate 64, and an inverter circuit 65.

An input terminal D of the flip-flop 61 is connected to the power supply terminal VDD, and into a clock terminal thereof, the time signal T₆₃ is input from the final-stage arithmetic element 13-63 included in the arithmetic unit 12.

An input terminal D of the flip-flop 62 is connected to the power supply terminal VDD, and into a clock terminal thereof, the time threshold value signal Th0 is input from the control circuit 19.

The first input terminal of the AND gate 64 is connected to an output terminal Q of the flip-flop 61, and a second input terminal thereof is connected to an output terminal Q of the flip-flop 62.

An input terminal D of the flip-flop 63 is connected to an output terminal of the AND gate 64, and to a clock terminal thereof, a clock signal SYS_CLK is supplied from the control circuit 19. The clock signal SYS_CLK is system clock repeating high level and low level in a constant cycle. The flip-flop 63 outputs the signal Ready from an output terminal Q thereof. The signal Ready is sent to the control circuit 19.

The output terminal Q of the flip-flop 63 is connected to reset terminals of the flip-flops 61 and 62 via the inverter circuit 65.

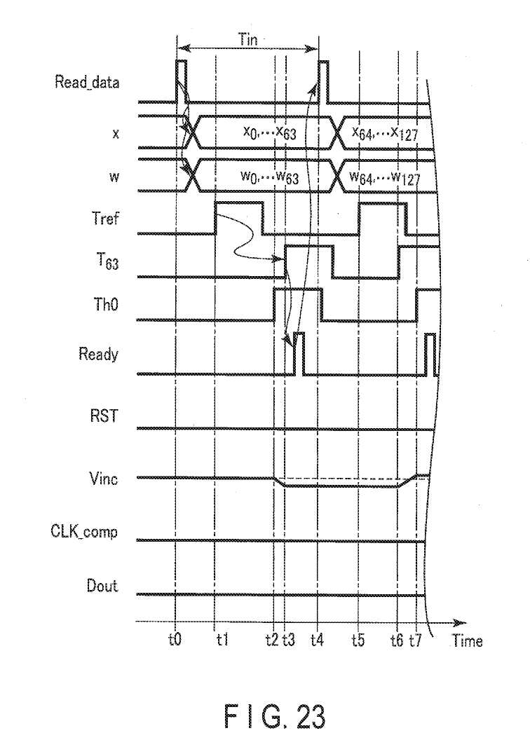

FIG. 23 is a timing diagram for illustrating a product-sum operation of the arithmetic device 7 according to the fourth embodiment.

At a time t2, the time threshold value signal Th0 becomes high level, and at a time t3, the time signal T₆₃ becomes high level. Then, the flip-flop 63 synchronizes with the clock signal SYS_CLK, and makes the signal Ready to be high level.

In response to the asserted signal Ready, the control circuit 19 asserts the signal Read_data. Thus, the input data x₆₄ to x₁₂₇ and the weight coefficients w₆₄ to w₁₂₇ for the second-time product-sum operation are input into the arithmetic unit 12. An upper limit may be set to the time from setting of x and w to the inputting of the signal Ready, thereby setting the next x and w without waiting for T₆₃.

According to the fourth embodiment, a timing for asserting the signal Read_data can be optimally set, and an interval Tin between the two signals Read_data can be made variable. Thereby, the time required for multiple repetitions of product-sum operations can be shortened.

In each embodiment described above, an example for identifying the numeral drawn in the image is shown. However, the purpose of each embodiment is not limited, and the image other than the numeral may be identified. Other than the image, sound may be identified. In this case, the sensor 2 may convert the sound into input data. Alternatively, the present invention may be applied to activity prediction of a chemical compound. The “inference” in the description above is a concept including not only “recognition”, which is to find what the numeral is, but also “classification” and “prediction.”

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An arithmetic device used for a neural network, comprising:
an arithmetic circuit that includes a plurality of arithmetic elements connected in series, and sequentially performs multiple repetitions of arithmetic processing, wherein each of the plurality of arithmetic elements receives a first time signal and a second time signal, and generates and outputs a third time signal and a fourth time signal obtained by delaying the first and second time signals by a time corresponding to a weight coefficient and input data;
a converter that converts a difference between the third and fourth time signals output from the arithmetic circuit into an analog signal or a digital signal for every multiple repetition of arithmetic processing;
an integrator that integrates a plurality of analog signals or a plurality of digital signals converted by the converter; and
a comparator that compares the integration result by the integrator with a reference value.

2. The arithmetic device according to claim 1, further comprising:
a first storage circuit that stores a plurality of weight coefficients corresponding to the multiple repetitions of arithmetic processing;
a second storage circuit that stores a plurality of input data corresponding to the multiple repetitions of arithmetic processing; and
a control circuit that inputs the plurality of weight coefficients and the plurality of input data into the arithmetic circuit sequentially for every multiple repetition of arithmetic processing.

3. The arithmetic device according to claim 1, wherein the converter increases a voltage level of the analog signal when the third time signal is faster than the fourth time signal, and decreases the voltage level of the analog signal when the third time signal is slower than the fourth time signal.

4. The arithmetic device according to claim 3, wherein the converter comprises:
a first flip-flop that includes an input terminal receiving a power supply voltage and a clock terminal receiving the third time signal;
a second flip-flop that includes an input terminal receiving the power supply voltage and a clock terminal receiving the fourth time signal;
a p-type transistor that includes a gate connected to an output terminal of the first flip-flop via an inverter and a drain connected to an output node;
an n-type transistor that includes a gate connected to an output terminal of the second flip-flop and a drain connected to the output node;
a first constant current source that includes a first terminal receiving the power supply voltage and a second terminal connected to a source of the p-type transistor; and
a second constant current source that includes a first terminal connected to a source of the n-type transistor and a second terminal receiving a ground voltage.

5. The arithmetic device according to claim 4, wherein the integrator comprises a capacitor connected to the output node.

6. The arithmetic device according to claim 1, wherein the converter comprises:
a plurality of first delay elements that delays the third time signal by a first time each;
second delay element that delays the fourth time signal by a second time longer than the first time; and
a plurality of flip-flops that respectively holds outputs of the plurality of first delay elements in response to an output of the second delay element being asserted.

7. The arithmetic device according to claim 6, wherein the converter further comprises a conversion unit connected to output terminals of the plurality of flip-flops, and converts a thermometer code output from the plurality of flip-flops into a binary code.

8. The arithmetic device according to claim 7, wherein the integrator is connected to an output terminal of the conversion unit, and adds a plurality of binary codes corresponding to the multiple repetitions of arithmetic processing.

9. The arithmetic device according to claim 1, wherein each of the arithmetic elements comprises a delay circuit that delays the time signal by a time corresponding to the weight coefficient.

10. The arithmetic device according to claim 9, wherein the arithmetic element further comprises a switching circuit that switches a path between the third time signal and the fourth time signal according to the input data.

11. An arithmetic method used for a neural network, comprising:
generating and outputting, by each of a plurality of arithmetic elements connected in series, a third time signal and a fourth time signal obtained by delaying a first time signal and a second time signal by a time corresponding to a weight coefficient and input data;
performing multiple repetitions of arithmetic processing sequentially by an arithmetic circuit including the plurality of arithmetic elements;
converting a difference between the third and fourth time signals output from a last-stage arithmetic element among the plurality of arithmetic elements into an analog signal or a digital signal for every multiple repetition of arithmetic processing;
integrating the plurality of converted analog signals or digital signals; and
comparing the integration result with a reference value.

12. The arithmetic method according to claim 11, further comprising:
storing a plurality of weight coefficients corresponding to the multiple repetitions of arithmetic processing;
storing a plurality of input data corresponding to the multiple repetitions of arithmetic processing; and
inputting the plurality of weight coefficients and the plurality of input data into the arithmetic circuit for every multiple repetition of arithmetic processing.

13. The arithmetic method according to claim 11, wherein the converting into the analog signal comprises increasing a voltage level of the analog signal when the third time signal is faster than the fourth time signal, and decreasing the voltage level of the analog signal when the third time signal is slower than the fourth time signal.

14. The arithmetic method according to claim 11, wherein the converting into the digital signal comprises:
delaying, by a plurality of first delay elements, the third time signal by a first time each;
delaying, by a second delay element, the fourth time signal by a second time longer than the first time;
holding, by a plurality of flip-flops, respective outputs of the plurality of first delay elements in response an output of the second delay element being asserted; and
generating the digital signal according to outputs of the plurality of flip-flops.

15. The arithmetic method according to claim 14, wherein the converting into the digital signal further comprises converting a thermometer code output from the plurality of flip-flops into a binary code.

16. The arithmetic method according to claim 15, wherein the integrating comprises adding a plurality of binary codes corresponding to the multiple repetitions of arithmetic processing.

17. The arithmetic method according to claim 11, wherein each of the arithmetic elements comprises a delay circuit that delays the time signal by a time corresponding to the weight coefficient.

18. The arithmetic method according to claim 17, wherein the arithmetic element further comprises a switching circuit that switches a path between the third time signal and the fourth time signal according to the input data.
